(19) United States
(12) Patent Application Publication
(10) Pub. No.: US 2026/0362862 A1
(43) Pub. Date: Nov. 12, 2026

(54) LIGHT-EMITTING DEVICE

(71) Applicant: Ennostar Corporation, Hsinchu City (TW)

(72) Inventors: Ching-Chi CHIANG, Hsinchu City (TW); Wei-Chung CHENG, Hsinchu City (TW); Pin-Feng HUNG, Hsinchu City (TW); Jia-Jhang KUO, Hsinchu City (TW); Jin-Wen LO, Hsinchu City (TW)

(21) Appl. No.: 19/668,683

(22) Filed: May 5, 2026

(30) Foreign Application Priority Data
May 7, 2025 (TW) 114117090

(51) Int. Cl. H10H 20/851; H10H 20/856

(52) U.S. Cl. CPC H10H 20/8514; H10H 20/856

(57) ABSTRACT

A light-emitting device includes a lead frame, a light-emitting element, a wavelength conversion layer, and a light-adjusting structure. The light-emitting element is disposed on the lead frame. The wavelength conversion layer covers the light-emitting element. The light-adjusting structure covers the light-emitting element and the wavelength conversion layer. The light-adjusting structure has a concave portion with a curved profile tapering toward the light-emitting element.

### CROSS REFERENCE TO RELATED APPLICATIONS

This application claims priority of Taiwan patent application No. 114117090, filed May 7, 2025, the entirety of which is incorporated by reference herein.

### TECHNICAL FIELD

The present disclosure relates to a light-emitting structure, and, in particular, it relates to a light-emitting device having a light-adjusting structure.

### BACKGROUND

Light-emitting diodes (LEDs) are light-emitting elements that are widely used as light sources in various electronic devices. With the extensive application of electronic devices, consumers' expectations for electronic devices have gradually increased.

To meet the high demand for high resolution and achieve a higher throughput, the size of light-emitting diodes is continuously being reduced, but this gives rise to various unresolved problems in the process of manufacturing light-emitting diodes, and these problems can affect the performance of light-emitting elements. For example, the existing LED package structures still exhibit issues such as a limited light-emitting area and low luminous efficiency.

Therefore, how to increase the light-emitting area and enlarge luminous efficiency remains a technical issue to be solved in the art.

### BRIEF SUMMARY

The present disclosure provides a light-emitting device. The light-emitting device includes a lead frame, a light-emitting element, a wavelength conversion layer, and a light-adjusting structure. The light-emitting element is disposed on the lead frame. The wavelength conversion layer covers the light-emitting element. The light-adjusting structure covers the light-emitting element and the wavelength conversion layer, in which the light-adjusting structure has a concave portion, and the concave portion has a curved profile tapering toward the light-emitting element.

### BRIEF DESCRIPTION OF THE DRAWINGS

Aspects of the present disclosure are best understood from the following detailed description when read with the accompanying figures. Note that in accordance with the standard practice in the industry, various features are not drawn to scale. In fact, the dimensions of the various features may be arbitrarily increased or reduced for clarity of discussion.

FIG. 1 is a perspective view of a light-emitting device, in accordance with some embodiments of the present disclosure.

FIG. 2 is a cross-sectional view taken along line A1-A1’ in FIG. 1, in accordance with some embodiments of the present disclosure.

FIG. 3 is a schematic cross-sectional view of a light-emitting device, in accordance with some embodiments of the present disclosure.

FIG. 4 is a schematic cross-sectional view of a light-emitting device, in accordance with some embodiments of the present disclosure.

FIG. 5 is a schematic cross-sectional view of a light-emitting device, in accordance with some embodiments of the present disclosure.

FIG. 6 is a schematic cross-sectional view of a light-emitting device, in accordance with some embodiments of the present disclosure.

FIG. 7 is a top view of a dam surrounding a wavelength conversion layer in FIG. 6, in accordance with some embodiments of the present disclosure.

FIG. 8 is a schematic cross-sectional view of a light-emitting device, in accordance with some embodiments of the present disclosure.

FIG. 9 is a top view of a dam surrounding a wavelength conversion layer in FIG. 8, in accordance with some embodiments of the present disclosure.

FIG. 10 is a perspective view of a light-emitting device, in accordance with other embodiments of the present disclosure.

FIG. 11 is a cross-sectional view taken along line A2-A2’ in FIG. 10, in accordance with other embodiments of the present disclosure.

FIG. 12 is a schematic cross-sectional view of a light-emitting device, in accordance with other embodiments of the present disclosure.

FIG. 13 is a schematic cross-sectional view of a light-emitting device, in accordance with other embodiments of the present disclosure.

FIG. 14 is a schematic cross-sectional view of a light-emitting device, in accordance with other embodiments of the present disclosure.

FIGS. 15A-15B are light pattern simulation diagrams of a light-emitting device according to an example.

FIGS. 16A-16B are light pattern simulation diagrams of a light-emitting device according to a comparative example.

FIGS. 17A-17B, 18A-18B, 19A-19B, 20A-20B, 21A-21B, and 22A-22B are schematic views of various stages of processes of a light-emitting device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the light-emitting device. Some of the features described below can be replaced or eliminated for different embodiments. Although some embodiments are discussed with operations performed in a particular order, these operations may be performed in another logical order.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

The existing light-emitting diode package structures employ a reflective flat cover, also referred to as a roof. Since the reflective flat cover has the reflective properties, it can make light emit toward the sides, thereby achieving a larger light-emitting area. However, since the reflective flat cover has the reflective properties, it causes the shading effect, causing a decrease in luminous efficiency.

To address the above issues, the light-emitting device of the present disclosure replaces the reflective flat cover with a light-adjusting structure having a curved profile that tapers toward the light-emitting element, thereby reducing the impact of the shading effect and increasing the light-emitting area and luminous efficiency.

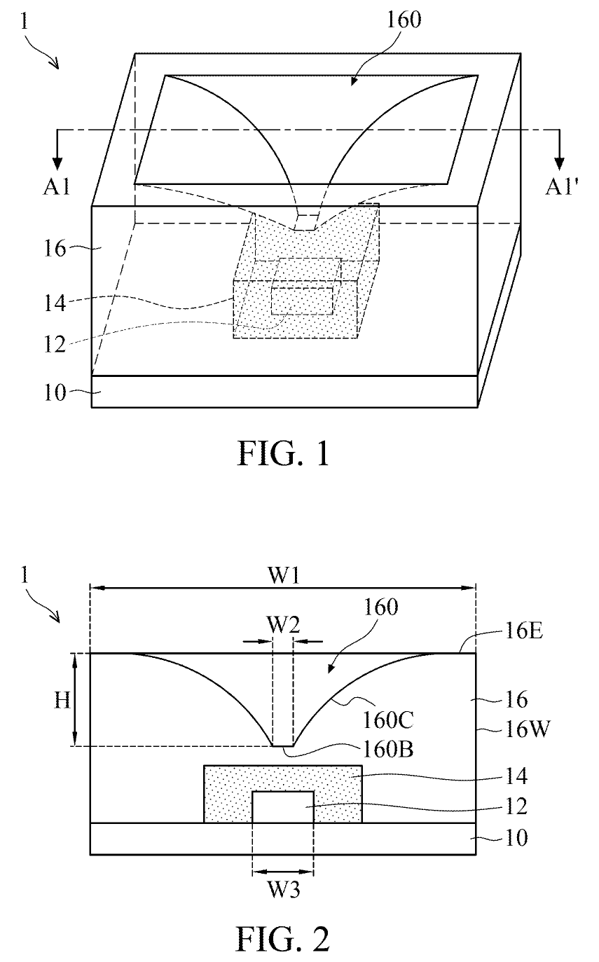

Referring to FIGS. 1 and 2, FIG. 1 is a perspective view of a light-emitting device 1, in accordance with some embodiments of the present disclosure. FIG. 2 is a cross-sectional view taken along line A1-A1’ in FIG. 1, in accordance with some embodiments of the present disclosure. As shown in FIGS. 1 and 2, the light-emitting device 1 includes a lead frame 10, a light-emitting element 12, a wavelength conversion layer 14, and a light-adjusting structure 16. The light-emitting element 12 is disposed on the lead frame 10. The wavelength conversion layer 14 covers the light-emitting element 12. The light-adjusting structure 16 covers the light-emitting element 12 and the wavelength conversion layer 14, in which the light-adjusting structure 16 has a concave portion 160, and the concave portion 160 has a curved profile 160C that tapers toward the light-emitting element 12. Specifically, the concave portion 160 of the light-adjusting structure 16 tapers from a top edge 16E of the light-adjusting structure 16 toward the light-emitting element, and the tapered concave portion 160 has the curved profile 160C. In some embodiments, the concave portion 160 of the light-adjusting structure 16 has an inverted flare shape. In some embodiments, the wavelength conversion layer 14 encapsulates the entire light-emitting element 12, and the top portion of the wavelength conversion layer 14 is located between the concave portion 160 of the light-adjusting structure 16 and the lead frame 10.

Referring to FIGS. 1 and 2, in some embodiments, the lead frame 10 may be a lead frame formed by laying conductive wires on a frame composed of a polymer material, wherein the conductive wires are electrically connected to the light-emitting element 12, for example, through wire bonding or other suitable processes to electrically connect the conductive wires of the lead frame 10 to the light-emitting element 12, but the present disclosure is not limited thereto. For example, the polymer material may be an epoxy resin, polyimide (PI), polypropylene (PP), a combination thereof, or other suitable polymer materials, but the present disclosure is not limited thereto. The material of the conductive wire may include a metal, a metal compound, a combination thereof, or other suitable conductive materials, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), or their alloys, but the present disclosure is not limited thereto. For example, the metal compound may be tantalum nitride (TaN), titanium nitride (TiN), tungsten silicide (WSi2), indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), but the present disclosure is not limited thereto.

Referring to FIGS. 1 and 2, in some embodiments, the light-emitting element 12 is an element configured to emit light with a specific color or a specific wavelength. For example, the light-emitting element 12 may be a blue light chip, an ultraviolet light chip, a yellow light chip, a red light chip, an infrared light chip, a combination thereof, or other suitable light-emitting elements, but the present disclosure is not limited thereto. In a specific embodiment, the light-emitting element 12 is a blue light chip. In some embodiments, the light-emitting element 12 may be a flip-chip light-emitting element, and thus the light-emitting element 12 may be electrically connected to the lead frame 10 through flip-chip bonding. In some embodiments, the light-emitting element 12 has a width W3.

Referring to FIGS. 1 and 2, in some embodiments, the wavelength conversion layer 14 is configured to convert the light emitted from the light-emitting element 12 into light having a specific color or a specific wavelength. For example, when the light-emitting element 12 is a blue light chip and the wavelength conversion layer 14 is a yellow phosphor encapsulant, the blue light emitted from the light-emitting element 12 may be converted by the wavelength conversion layer 14 into white light, but the present disclosure is not limited thereto. In some embodiments, the wavelength conversion layer 14 may be in direct contact with the light-emitting element 12, such that the light emitted by the light-emitting element 12 may be directly converted by the wavelength conversion layer 14. For example, the wavelength conversion layer 14 may be a phosphor encapsulant, and the phosphor encapsulant contains a matrix and a light conversion material dispersed within the matrix, but the present disclosure is not limited thereto. The matrix may be silicone, epoxy resin (epoxy), a combination thereof, or other suitable light-transmissive materials. In some embodiments, the material of the matrix of the wavelength conversion layer 14 is the same as that of the light-adjusting structure 16, such that the matrix of the wavelength conversion layer 14 has the same refractive index as the light-adjusting structure 16. The wavelength conversion material may include a red light conversion material, a blue light conversion material, a green light conversion material, a yellow light conversion material, a combination thereof, or other suitable light conversion materials. In some embodiments, the red light conversion material may be red quantum dots or red phosphor, but the present disclosure is not limited thereto. For example, the red light conversion material may be (Sr,Ca)AlSiN₃:Eu²⁺, Ca₂Si₅N₈:Eu²⁺, Sr (LiAl₃N₄):Eu²⁺, manganese-doped red fluoride phosphor, a combination thereof, or other suitable analogs, but the present disclosure is not limited thereto. The manganese-doped red fluoride phosphor may be K₂GeF₆:Mn⁴⁺, K₂SiF₆:Mn⁴⁺, K₂TiF₆:Mn⁴⁺, a combination thereof, or other suitable analogs, but the present disclosure is not limited thereto. In some embodiments, the blue light conversion material may be blue quantum dots or blue phosphor, but the present disclosure is not limited thereto. In some embodiments, the green light conversion material may be green quantum dots or green phosphor, but the present disclosure is not limited thereto. For example, the green light conversion material may be lutetium aluminum garnet (LuAG) phosphor, yttrium aluminum garnet (YAG) phosphor, Sialon (β-SiAlON) phosphor, or silicate phosphor, a combination thereof, or other suitable analogs, but the present disclosure is not limited thereto. In some embodiments, the yellow light conversion material may be yellow quantum dots or yellow phosphor. For example, the yellow light conversion material may be yttrium aluminum garnet (YAG) phosphor. In some embodiments, the light-emitting element 12 may be a blue light chip, and the wavelength conversion layer 14 may include the yellow light conversion material, or the wavelength conversion layer 14 may include a combination of the green light conversion material and the red light conversion material. For example, the wavelength conversion layer 14 may include green Sialon phosphor and red K₂SiF₆:Mn⁴⁺. In some embodiments, the wavelength conversion layer 14 may include a combination of the green light conversion material and two red light conversion materials. For example, the wavelength conversion layer 14 may include green Sialon phosphor, red K₂SiF₆:Mn⁴⁺, and red (Sr,Ca)AlSiN₃:Eu²⁺.

Referring to FIGS. 1 and 2, in some embodiments, the light-adjusting structure 16 is configured to allow a portion of light to pass directly through, while deflecting another portion of light toward the sides via the curved profile 160C of the concave portion 160 of the light-adjusting structure 16, thereby expanding the light beam angle. In some embodiments, the light-adjusting structure 16 is a lens. The light-adjusting structure 16 has a transmittance for the peak emission wavelength of the light-emitting element 12 greater than about 50%, for example, greater than about 60%, greater than about 70%, greater than about 80%, greater than about 90%, greater than about 95%, or greater than about 99%, but the present disclosure is not limited thereto. In some embodiments, the material of the light-adjusting structure 16 is a light-transmissive material. In other embodiments, the light-adjusting structure 16 includes a light-transmissive material and scattering particles, with the scattering particles dispersed within the light-transmissive material, in which the concentration of the scattering particles within the light-transmissive material is less than 50% (w/w). In other embodiments, the concentration of the scattering particles within the light-transmissive material may be about 0.1% (w/w) to about 20% (w/w), for example, about 0.2% (w/w), about 0.3% (w/w), about 0.5% (w/w), about 0.7% (w/w), about 1% (w/w), about 2% (w/w), about 3% (w/w), about 4% (w/w), about 5% (w/w), about 10% (w/w), or about 15% (w/w), but the present disclosure is not limited thereto. For example, the light-transmissive material may be silicone, epoxy resin (epoxy), a combination thereof, or other suitable light-transmissive materials. For example, the scattering particles may be silicon dioxide (SiO2), a combination thereof, or other suitable scattering particles. In some embodiments, the concave portion 160 of the light-adjusting structure 16 includes a flat bottom surface 160B. The entire light-adjusting structure 16 has a width W1. The width W1 may be about 1.5 mm to about 2.5 mm, for example, about 1.6 mm, about 1.7 mm, about 1.8 mm, about 1.9 mm, about 2.0 mm, about 2.1 mm, about 2.2 mm, about 2.3 mm, or about 2.4 mm, but the present disclosure is not limited thereto. In some embodiments, the width W1 of the light-adjusting structure 16 is greater than the width W3 of the light-emitting element 12 to ensure that the light-adjusting structure 16 may cover the entire light-emitting element 12. In some embodiments, the bottom surface 160B of the concave portion 160 of the light-adjusting structure 16 has a width W2, and the width W2 may be greater than about 0.02 mm. In some embodiments, the width W2 may be about 0.10 to about 0.30 mm, for example, about 0.15 mm, 0.20 mm, or 0.25 mm, but the present disclosure is not limited thereto. In some embodiments, a height H of the concave portion 160 of the light-adjusting structure 16 may be greater than about 0.1 mm. In some embodiments, the height H may be about 0.3 mm to about 0.8 mm, for example, about 0.4 mm, about 0.50 mm, about 0.60 mm, or about 0.70 mm, but the present disclosure is not limited thereto. In some embodiments, the ratio of the width W2 to the height H may be about 0.10 to about 1.00, for example, about 0.30, about 0.50, about 0.70, or about 0.90, but the present disclosure is not limited thereto. In some embodiments, the ratio of the width W1 to the height H may be about 1.5 to about 8.5, for example, about 2.0, about 2.5, about 3.0, about 3.5, about 4.0, about 4.5, about 5.0, about 5.5, about 6.0, about 6.5, about 7.0, about 7.5, or about 8.0, but the present disclosure is not limited thereto. With the above-described width W1 to height H ratio, the light-adjusting structure 16 can have a good light divergence angle, allowing light incident on the light-adjusting structure 16 to emit toward the sides easily, thereby increasing the light-emitting area. In some embodiments, the concave portion 160 of the light-adjusting structure 16 has the inverted flare shape, the width W1 is about 2.5 mm, the width W2 is about 0.125 mm, the height H is about 0.55 mm, the width-to-height ratio (W1/H) is about 4.545, the radius of curvature of the curved profile 160C is about 1.3 mm, and the width-to-height ratio (W2/H) is about 0.227. In some embodiments, the radius of curvature of the curved profile 160C of the concave portion 160 of the light-adjusting structure 16 may be greater than about 0.02 mm. In some embodiments, the radius of curvature of the curved profile 160C may be about 0.05 mm to about 2.00 mm. With above-described radius of curvature, allowing light incident on the concave portion 160 of the light-adjusting structure 16 to emit toward the sides easily, thereby widening the beam angle. For example, the radius of curvature of the curved profile 160C may be about 0.10 mm, about 0.20 mm, about 0.30 mm, about 0.40 mm, about 0.50 mm, about 0.60 mm, about 0.70 mm, about 0.80 mm, about 0.90 mm, about 1.00 mm, about 1.10 mm, about 1.20 mm, about 1.30 mm, about 1.40 mm, about 1.50 mm, about 1.60 mm, about 1.70 mm, about 1.80 mm, or about 1.90 mm, but the present disclosure is not limited thereto. In some embodiments, the radius of curvature of the curved profile 160C may be about 1.0 mm to about 1.5 mm.

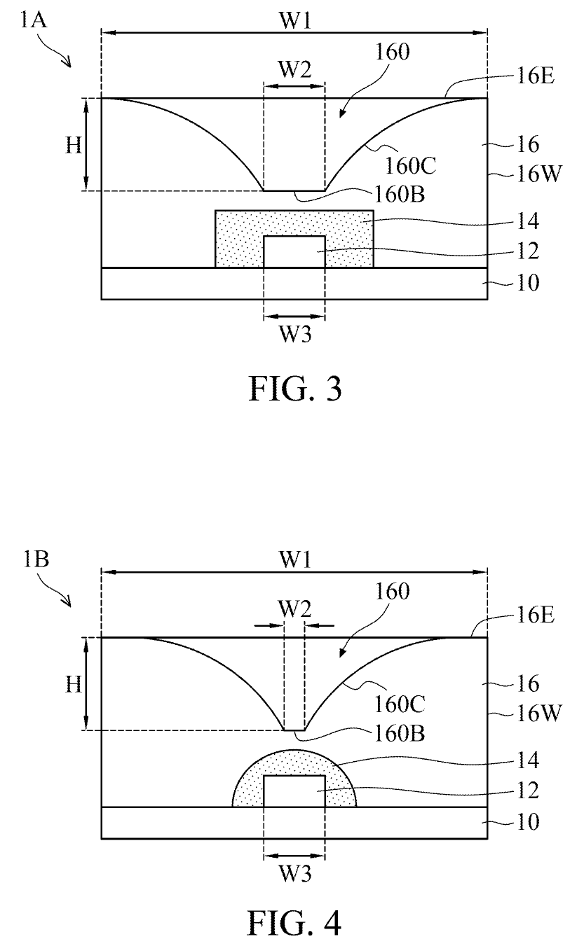

Referring to FIG. 3, FIG. 3 is a schematic cross-sectional view of a light-emitting device 1A, in accordance with further embodiments of the present disclosure. Compared to the light-emitting device 1 illustrated in FIG. 2, the light-adjusting structure 16 of the light-emitting device 1A illustrated in FIG. 3 has a smaller radius of curvature, a greater curvature, and a wider bottom surface width. By providing the light-adjusting structure 16 with a greater curvature, the transmittance of the top surface can be controlled, thereby enabling control of the light pattern shape. By providing the concave portion 160 of the light-adjusting structure 16 with a wider bottom surface 160 B, the transmittance of the top surface can be controlled, thereby enabling control of the ratio of the luminance at the top surface and the luminance at the side surface. In a specific embodiment, the width W1 is about 2.5 mm, the width W2 is about 0.250 mm, the height H is about 0.750 mm, the width-to-height ratio (W1/H) is about 3.333, the width-to-height ratio (W2/H) is about 0.3333, and the radius of curvature of the curved profile 160C is about 1.2 mm.

Referring to FIG. 4, FIG. 4 is a schematic cross-sectional view of a light-emitting device 1B, in accordance with further embodiments of the present disclosure. Compared to the light-emitting device 1 illustrated in FIG. 2, in which the wavelength conversion layer 14 is rectangular, the wavelength conversion layer 14 of the light-emitting device 1B illustrated in FIG. 4 is hemispherical. By configuring the wavelength conversion layer 14 to be hemispherical, the luminous flux of lateral light and the luminous flux directed toward the curved profile 160C can be increased. However, the present disclosure is not limited thereto, and the wavelength conversion layer 14 may be adjusted to other suitable shapes as needed.

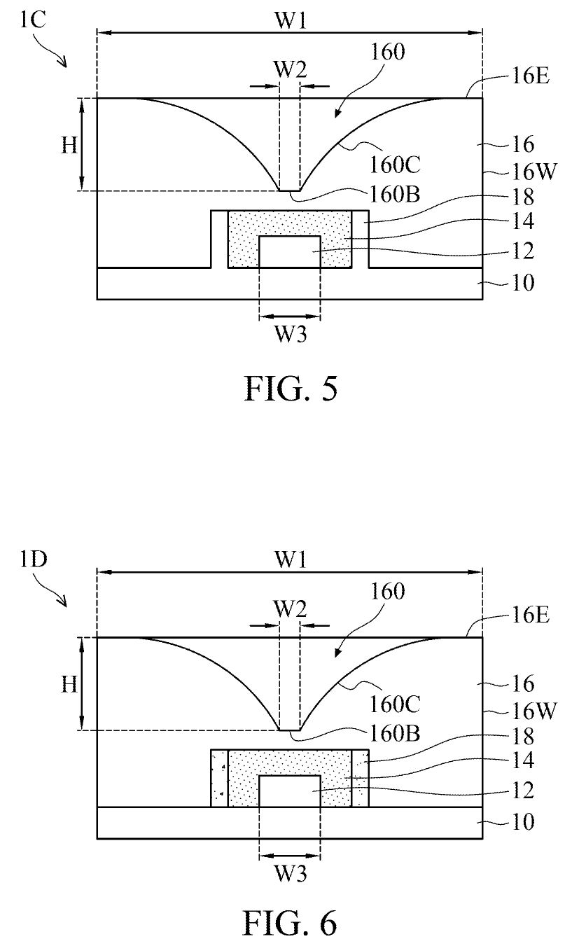

Referring to FIGS. 5 and 6, FIG. 5 is a schematic cross-sectional view of a light-emitting device 1C, in accordance with further embodiments of the present disclosure. FIG. 6 is a schematic cross-sectional view of a light-emitting device 1D, in accordance with further embodiments of the present disclosure. Compared to the light-emitting device 1 illustrated in FIG. 2, the light-emitting device 1C illustrated in FIG. 5 and light-emitting device 1D illustrated in FIG. 6 further include a dam 18, the dam 18 is disposed between the lead frame 10 and the light-adjusting structure 16, and the dam 18 surrounds the light-emitting element 12 and the wavelength conversion layer 14. Referring to FIG. 5, in some embodiments, the dam 18 and the lead frame 10 are integrally formed. Referring to FIG. 6, in some embodiments, the dam 18 is additionally disposed on the lead frame 10. In other words, the dam 18 and the lead frame 10 are not integrally formed. Although in FIGS. 5 and 6 the top surface of the wavelength conversion layer 14 is level with the top surface of the dam 18, in other embodiments, the top surface of the wavelength conversion layer 14 may be lower than the top surface of the dam 18.

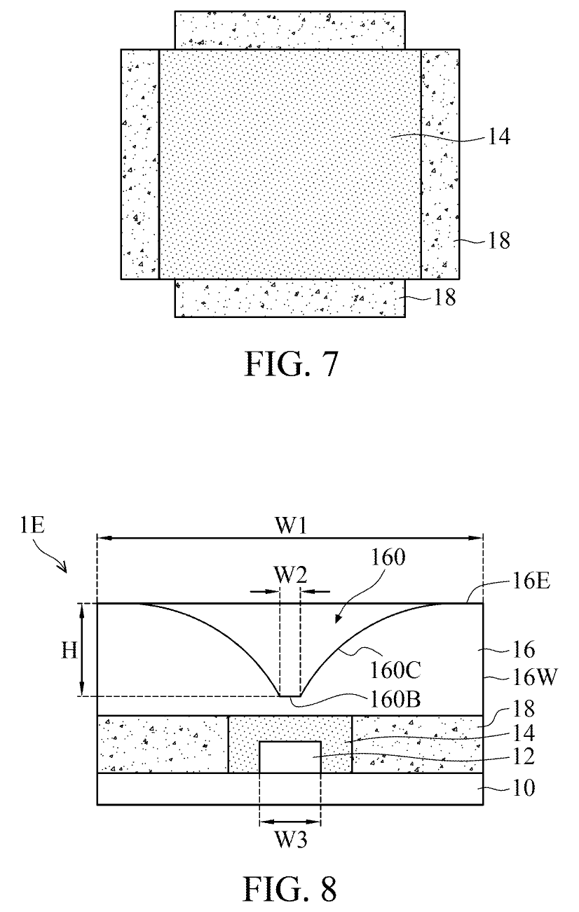

Referring to FIG. 7, FIG. 7 is a top view of a dam 18 surrounding the wavelength conversion layer 14 in FIG. 6, in accordance with some embodiments of the present disclosure. The dam 18 illustrated in FIG. 7 exposes the top surface of the wavelength conversion layer 14 and the dam 18 includes a plurality of discontinuous segments, that is, the dam 18 includes gaps. The gaps expose portions of the wavelength conversion layer 14, but the present disclosure is not limited thereto. Referring to FIG. 7, in a specific embodiment, the dam 18 is composed of four segments surrounding the wavelength conversion layer 14, wherein the four segments are arranged in two pairs of parallel segments and are not connected to each other, thereby exposing portions of the wavelength conversion layer 14. Since light is generally restricted and cannot pass through right-angle structures, resulting in reduced luminous efficiency, the dam 18 is configured as multiple discontinuous segments, thereby exposing corner portions of the wavelength conversion layer 14. This allows light to directly emit through the gaps of the dam 18, effectively increasing the light-emitting area and enhancing brightness.

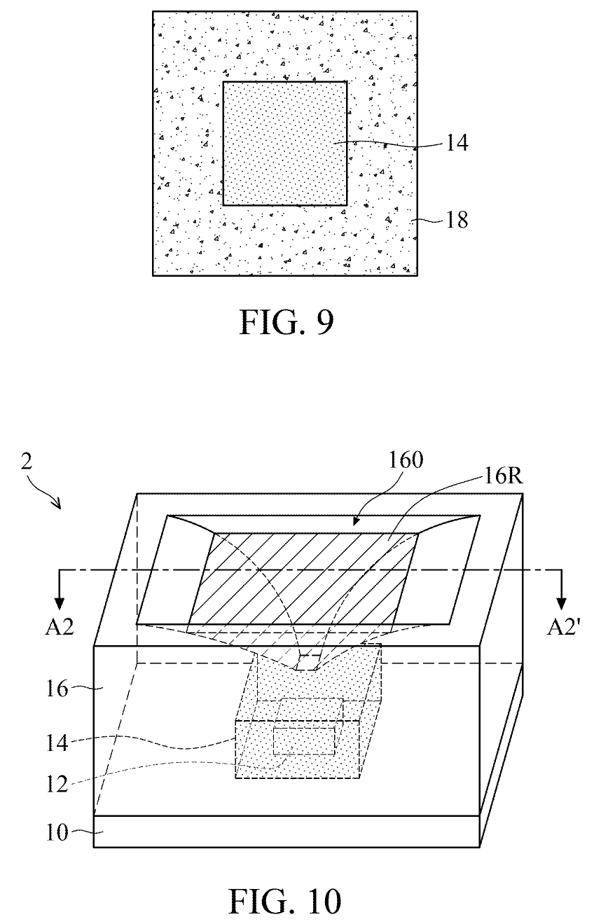

Referring to FIGS. 8 and 9, FIG. 8 is a schematic cross-sectional view of a light-emitting device 1E, in accordance with some embodiments of the present disclosure. FIG. 9 is a top view of the dam 18 surrounding the wavelength conversion layer 14 in FIG. 8, in accordance with some embodiments of the present disclosure. Compared to the light-emitting device 1D illustrated in FIG. 6, the dam 18 of the light-emitting device 1E illustrated in FIG. 8 is disposed between the lead frame 10 and the light-adjusting structure 16, and the sidewall of the dam 18 is aligned with the sidewall 16W of the light-adjusting structure 16. In some embodiments, the sidewall of the dam 18, the sidewall 16W of the light-adjusting structure 16, and the sidewall of the lead frame 10 are aligned. The dam 18 illustrated in FIG. 9 exposes the top surface of the wavelength conversion layer 14, but the dam 18 does not include a gap. Although the dam 18 is illustrated as an integrally formed structure surrounding the wavelength conversion layer 14 in FIG. 9, the present disclosure is not limited thereto. In other embodiments, the dam 18 may also be a structure formed by a plurality of segments joined together. Compared to the luminous efficiency (as a reference value of 100%) and light spot area (as a reference value of 100%) of an existing light-emitting device with a reflective flat cover, experimental results have confirmed that the light-emitting device 1E of FIG. 8 can enhance luminous efficiency to 105% and change the light spot area to 91%. The light-emitting device 1E can enhance luminous efficiency since the light-adjusting structure 16 has the curved profile 160C that tapers toward the light-emitting element 12, thereby enhancing the amount of transmitted light. In the present embodiment and the embodiments described hereinafter, the existing light-emitting device with the reflective flat cover refers to a device that the light-adjusting structure 16 of the light-emitting device 2A of FIG. 12 is replaced with a reflective flat cover without the concave portion 160 and having a flat shape.

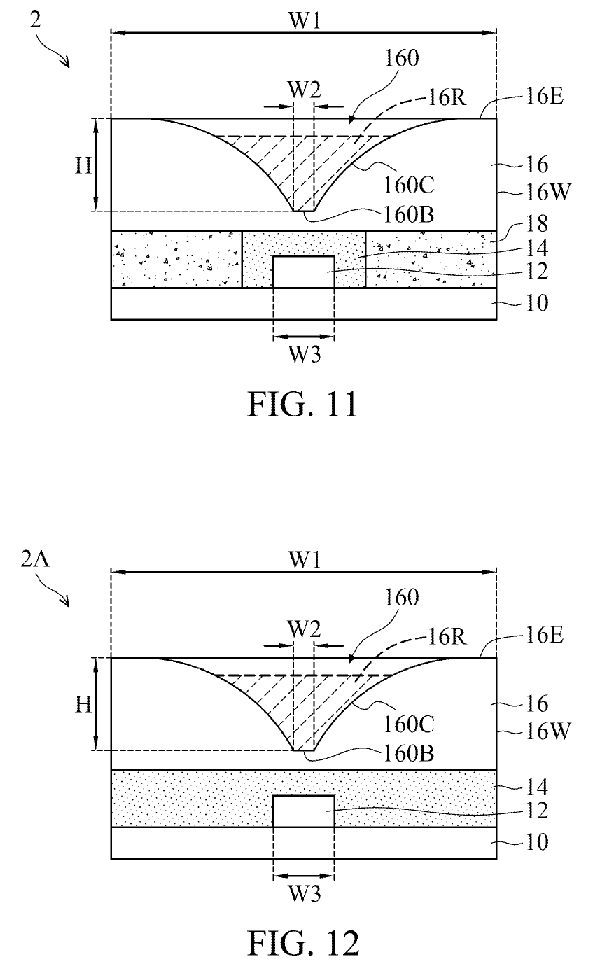

Referring to FIGS. 10 and 11, FIG. 10 is a perspective view of a light-emitting device 2, in accordance with other embodiments of the present disclosure. FIG. 11 is a cross-sectional view taken along line A2-A2’ in FIG. 10, in accordance with other embodiments of the present disclosure. Compared to the light-emitting device 1E illustrated in FIG. 8, the light-emitting device 2 illustrated in FIG. 10 further includes a reflective layer 16R, and the reflective layer 16R is disposed in the concave portion 160 of the light-adjusting structure 16. In some embodiments, the reflective layer 16R only partially fills the concave portion 160, in other words, the reflective layer 16R does not completely fill the entire concave portion 160. By disposing the reflective layer 16R within the concave portion 160, more light can be reflected by the reflective layer 16R toward the sides, thereby increasing the light-emitting area. Meanwhile, since the reflective layer 16R only partially fills the concave portion 160, part of light can still directly pass through the unfilled portions of the concave portion 160, thereby reducing the shading effect caused by the reflective layer 16R. The material of the reflective layer 16R may be a reflective material, and the reflective material may include a light-transmissive material and a reflective filler, in which the reflective filler is dispersed within the light-transmissive material. The concentration of the reflective filler within the light-transmissive material may be about 0.1% (w/w) to about 30% (w/w), for example, about 0.2% (w/w), about 0.3% (w/w), about 0.5% (w/w), about 0.7% (w/w), about 1% (w/w), about 2% (w/w), about 3% (w/w), about 4% (w/w), about 5% (w/w), about 10% (w/w), about 15% (w/w), about 20% (w/w), or about 25% (w/w), but the present disclosure is not limited thereto. For example, the light-transmissive material of the reflective layer 16R may be silicone, epoxy resin (epoxy), a combination thereof, or other suitable light-transmissive materials. For example, the reflective filler may be titanium dioxide (TiO2) or other suitable reflective fillers, but the present disclosure is not limited thereto. In some embodiments, the filling ratio of the reflective layer 16R in the concave portion 160 may be about 0.1% to about 30%, for example, about 0.2%, about 0.3%, about 0.5%, about 0.7%, about 1%, about 2%, about 3%, about 5%, about 10%, about 15%, about 20%, or about 25%, but the present disclosure is not limited thereto. Compared to the luminous efficiency (as the reference value of 100%) and light spot area (as the reference value of 100%) of the existing light-emitting device with the reflective flat cover, experimental results have confirmed that the light-emitting device 2 of FIGS. 10 and 11, which employs the configuration having the light-adjusting structure 16 with the curved profile 160C together with the reflective layer 16R, the light-emitting device 2 can enhance luminous efficiency to 108% and change the light spot area to 96%. The light-emitting device 2 can further increase the luminous efficiency and light spot area since the reflective layer 16R reflects a portion of light, increasing light emitted toward the sides, thereby enlarging the light spot area. In addition, the scattering particles within the light-adjusting structure 16 scatter the light, causing part of the light to be directed toward the wavelength conversion layer 14, which is then excited to generate more light, thereby enhancing the luminous efficiency.

Referring to FIGS. 11, in other embodiments, the reflective layer 16R has the inverted flare shape, which may also be referred to as an inverted trapezoidal or inverted funnel shape. In other embodiments, the orthogonal projection area of the reflective layer 16R onto the lead frame 10 is larger than the orthogonal projection area of the light-emitting element 12 onto the lead frame 10. In other embodiments, the orthogonal projection area of the reflective layer 16R onto the lead frame 10 is larger than the sum of the orthogonal projection areas of the light-emitting element 12 and the wavelength conversion layer 14 onto the lead frame 10. In other embodiments, the orthogonal projection area of the reflective layer 16R onto the lead frame 10 is equal to the sum of the orthogonal projection areas of the light-emitting element 12 and the wavelength conversion layer 14 onto the lead frame 10. In other embodiments, the orthogonal projection area of the reflective layer 16R onto the lead frame 10 is smaller than the sum of the orthogonal projection areas of the light-emitting element 12 and the wavelength conversion layer 14 onto the lead frame 10.

Referring to FIG. 12, FIG. 12 is a schematic cross-sectional view of a light-emitting device 2A, in accordance with further embodiments of the present disclosure. Compared to the light-emitting device 2 illustrated in FIG. 11, in the light-emitting device 2A illustrated in FIG. 12, the dam 18 of FIG. 11 is replaced with the wavelength conversion layer 14, such that the wavelength conversion layer 14 covers the light-emitting element 12 and the upper surface of the lead frame 10. Compared to the luminous efficiency (as the reference value of 100%) and light spot area (as the reference value of 100%) of the existing light-emitting device with the reflective flat cover, experimental results have confirmed that the light-emitting device 2A of FIG. 12 can enhance luminous efficiency to 113% and change the light spot area to 103%. The light-emitting device 2A can further increase luminous efficiency and light spot area since the light-emitting device 2A replaces the dam 18 with the wavelength conversion layer 14, thereby causing more reflected or scattered light to reach the wavelength conversion layer 14,, which is then excited to emit more light, thereby enhancing luminous efficiency. In addition, the light can also be emitted toward the sides through the wavelength conversion layer 14. Otherwise, the reflected or scattered light can excite a part of the wavelength conversion layer 14 near the sides, such that the excited light can also be emitted toward the sides, thereby increasing the light spot area.

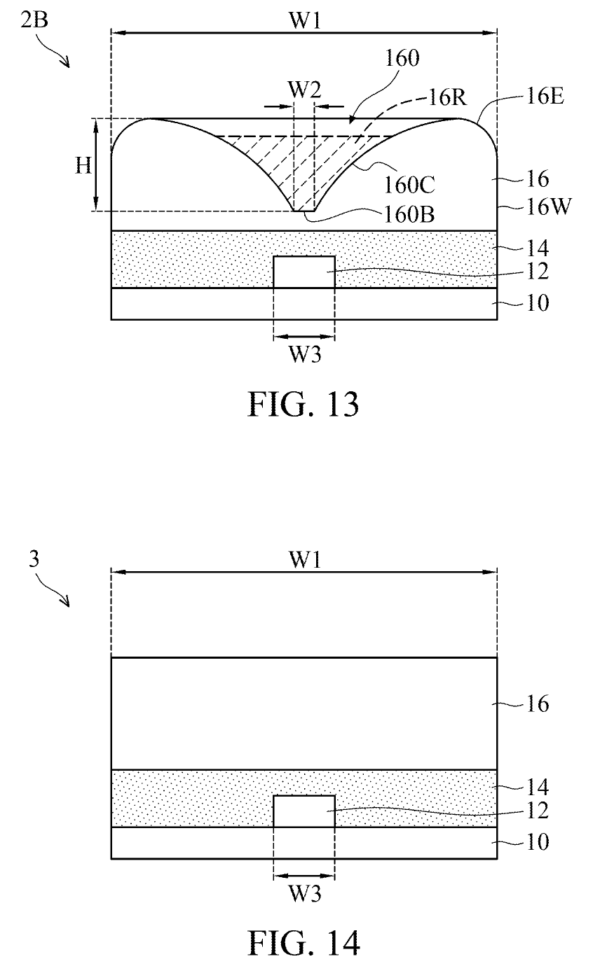

Referring to FIG. 13, FIG. 13 is a schematic cross-sectional view of a light-emitting device 2B, in accordance with other embodiments of the present disclosure. Compared to the light-emitting device 2 illustrated in FIG. 11, in the light-emitting device 2B illustrated in FIG. 13, the dam 18 of FIG. 11 is replaced with the wavelength conversion layer 14, such that the wavelength conversion layer 14 covers the light-emitting element 12 and the upper surface of the lead frame 10. In addition, the outer side of the top edge 16E of the light-adjusting structure 16 is a chamfered structure, in which the chamfered structure of the top edge 16E in the cross-sectional view of FIG. 13 represents the chamfered structure at the top portion of the light-adjusting structure 16 in the perspective view. In some embodiments, the chamfered structure is a rounded corner (R-corner), and in the schematic cross-sectional view of FIG. 13, both the left and right sides of the top portion of the light-adjusting structure 16 are arc-shaped. In some embodiments, the radius of curvature of the chamfered structure of the light-adjusting structure 16 may be greater than 0.02 mm. In some embodiments, the radius of curvature of the chamfered structure of the light-adjusting structure 16 may be about 0.1 mm to about 0.5 mm, for example, about 0.2 mm, about 0.3 mm, or about 0.4 mm. Compared to the luminous efficiency (as the reference value of 100%) and light spot area (as the reference value of 100%) of the existing light-emitting device with the reflective flat cover, experiments results have confirmed that the light-emitting device 2B of FIG. 13 can enhance luminous efficiency to 115% and change the light spot area to 105%. The light-emitting device 2B can further increase luminous efficiency and light spot area since the chamfered structure of the light-adjusting structure 16 is the rounded corner, allowing light to pass outward through the light-adjusting structure 16 more effectively, thereby enhancing luminous efficiency and enlarging light spot area.

Referring to FIG. 14, FIG. 14 is a schematic cross-sectional view of a light-emitting device 3, in accordance with further embodiments of the present disclosure. Compared to the light-emitting device 2A illustrated in FIG. 12, in the light-emitting device 3 illustrated in FIG. 14, the light-adjusting structure 16 is a light-scattering flat top cover. The material of the light-adjusting structure 16 of the light-emitting device 3 may include a light-transmissive material and scattering particles, and the scattering particles are dispersed within the light-transmissive material. For example, the light-transmissive material may be silicone, epoxy resin, a combination thereof, or other suitable light-transmissive materials. For example, the scattering particles may be silicon dioxide, other suitable scattering particles, or a combination thereof. For example, the concentration of the scattering particles within the light-transmissive material may be about 0.1% (w/w) to about 5% (w/w), such as about 0.2% (w/w), about 0.3% (w/w), about 0.5% (w/w), about 0.7% (w/w), about 1% (w/w), about 2% (w/w), about 3% (w/w), or about 4% (w/w), but the present disclosure is not limited thereto. Compared to the luminous efficiency (as the reference value of 100%) and light spot area (as the reference value of 100%) of the existing light-emitting device with the reflective flat cover, experimental results have confirmed that the light-emitting device 3 of FIG. 14 can enhance luminous efficiency to 125% and change the light spot area to 68%. The light-emitting device 3 can further enhance luminous efficiency by incorporating the aforementioned ratio of scattering particles within the material of the light-adjusting structure 16, such that the light is scattered and part of the scattered light is directed toward the wavelength conversion layer 14 to excite additional light emission. In addition, since the material of the light-adjusting structure 16 is still mainly the light-transmissive material, most of the light is emitted upward, thereby enhancing the luminous efficiency.

It should be noted that although various aspects of light-emitting devices (such as light-emitting devices 1, 1A, 1B, 1C, 1D, 1E, 2, 2A, 2B, 3) have been described above according to certain embodiments, the present disclosure is not limited thereto. Those skilled in the art may arbitrarily adopt some of the specific configurations mentioned above, or modify the specific configurations to further increase the light-emitting surface area of the light-emitting device or reduce the impact of shading effect. For example, the wavelength conversion layer 14 with hemispherical shape in the light-emitting device 1B (as shown in FIG. 4) may also be applied to light-emitting devices 1, 1A, 1C, 1D, 1E, 2, 2A, 2B, 3 (as shown in FIGS. 1-3, 5-6, 8, and 10-14). For example, although the dam 18 and the lead frame 10 are shown as integrally formed only in the light-emitting device 1C (as shown in FIG. 5), in practice, the dam 18 of the light-emitting device 1E (as shown in FIG. 8) and the light-emitting device 2 (as shown in FIG. 11) may also be integrally formed with the lead frame 10. For example, although the structure that the reflective layer 16R fills the concave portion 160 is only illustrated in the light-emitting devices 2, 2A, 2B (as shown in FIGS. 10, 11, 12 and 13), the reflective layer 16R may also fill the concave portion 160 in the light-emitting devices 1, 1A, 1B, 1C, 1D, and 1E (as shown in FIGS. 1-6 and 8). For example, although the wavelength conversion layer 14 is illustrated as covering the light-emitting element 12 and the entire upper surface of the lead frame 10 only in the light-emitting devices 2A, 2B, 3, in practice, the wavelength conversion layer 14 of light-emitting devices 1, 1A, 1B (as shown in FIGS. 1-4) may also be adjusted to cover the light-emitting element 12 and the entire upper surface of the lead frame 10. For example, although the light-adjusting structure 16 is illustrated as having the chamfered structure at the top portion only in the light-emitting device 2B, in practice, the light-adjusting structure 16 in the light-emitting devices 1, 1A, 1B, 1C, 1D, 1E, 2, 2A, 3 (as shown in FIGS. 1-3, 5-6, 8, 10-12, and 14) may also be designed to have the chamfered structure. For example, although the light-adjusting structure 16 is shown as the light-scattering flat top cover only in the light-emitting device 3, in practice, the light-adjusting structure 16 in the light-emitting devices 1, 1A, 1B, 1C, 1D, 1E, 2, 2A, 2B (as shown in FIGS. 1-3, 5-6, 8, and 10-13) may also be modified to be the light-scattering flat top cover.

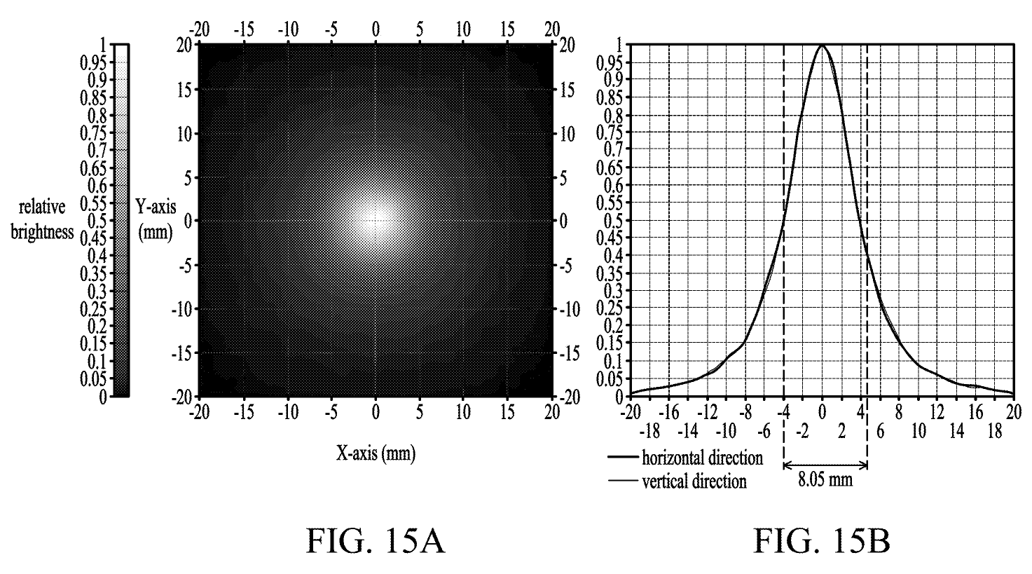

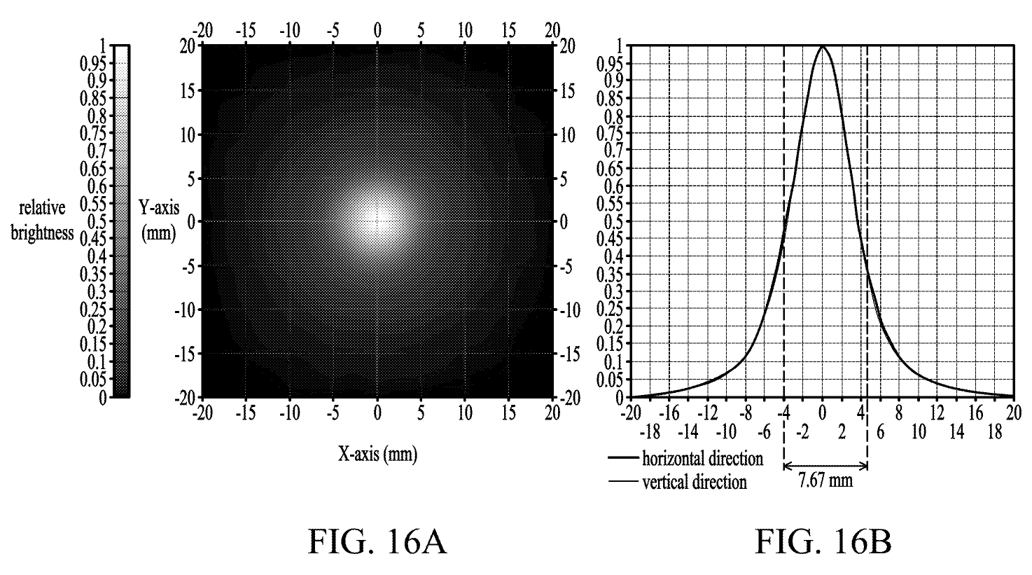

FIGS. 15A-15B are the light pattern simulation results of the light-emitting device1 of FIGS. 1-2 of the present disclosure. FIGS. 16A-16B are the light pattern simulation results of a comparative example. In the comparative example, the light-adjusting structure with a concave portion 160 having a curved profile 160C is replaced with a V-shaped cut (V-cut) light-adjusting structure. Simulations have confirmed that compared to the light spot diameter of only 7.67 mm in the comparative example, the light-emitting device 1 of FIGS. 1-2 can further enhance the light spot diameter to 8.05 mm. This is because it has a light-adjusting structure 16 with a curved profile 160C tapering toward the light-emitting element 12, thereby increasing the light emission angle and enlarging the light-emitting area.

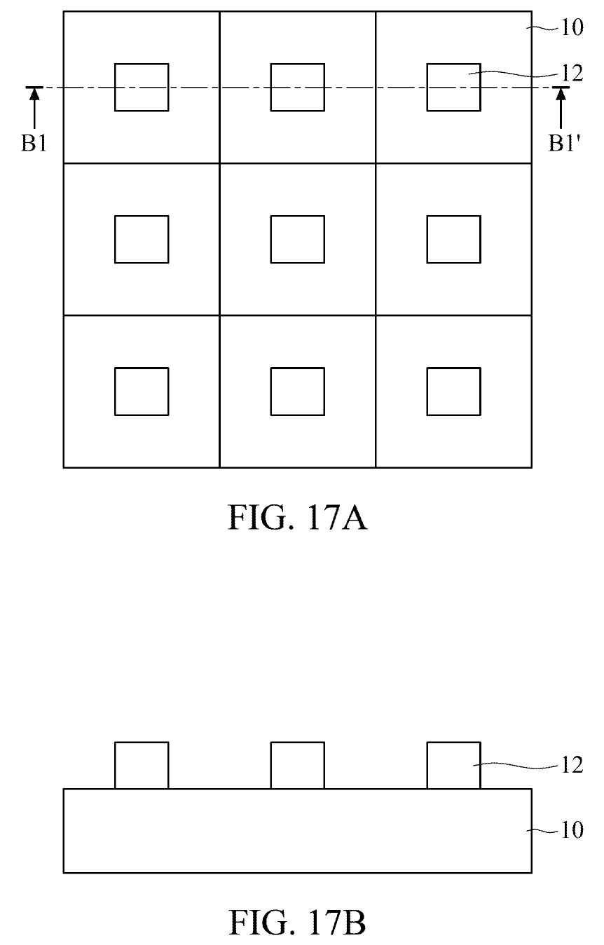

The following is an exemplary description of a method for manufacturing a light-emitting device. FIGS. 17A-17B, 18A-18B, 19A-19B, 20A-20B, and 21A-21B are schematic views of various stages of processes of the light-emitting device, in accordance with some embodiments of the present disclosure, and the process for producing the light-emitting device 1E illustrated in FIG. 8 is used as an example.

Referring to FIGS. 17A and 17B, first, the light-emitting element 12 is mounted onto the lead frame 10. Referring to FIGS. 17A and 17B, FIG. 17A is a top view of the light-emitting element 12 disposed on the lead frame 10, in accordance with some embodiments of the present disclosure. FIG. 17B is a cross-sectional view taken along line B1-B1’ in FIG. 17A. For example, the light-emitting element 12 may be mounted onto the lead frame 10 through a die bonding process or other suitable processes, but the present disclosure is not limited thereto.

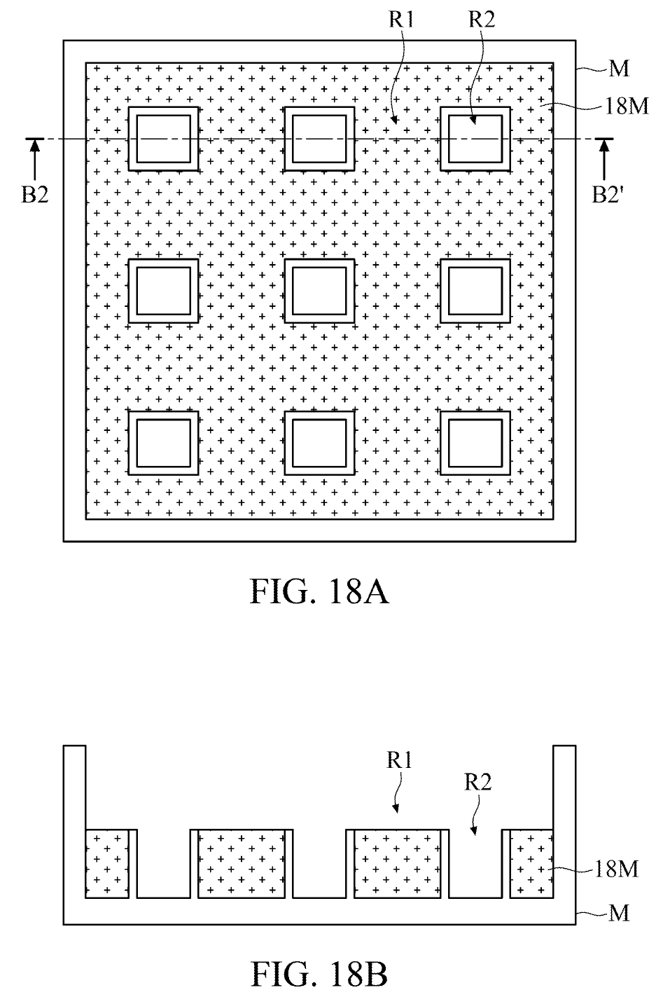

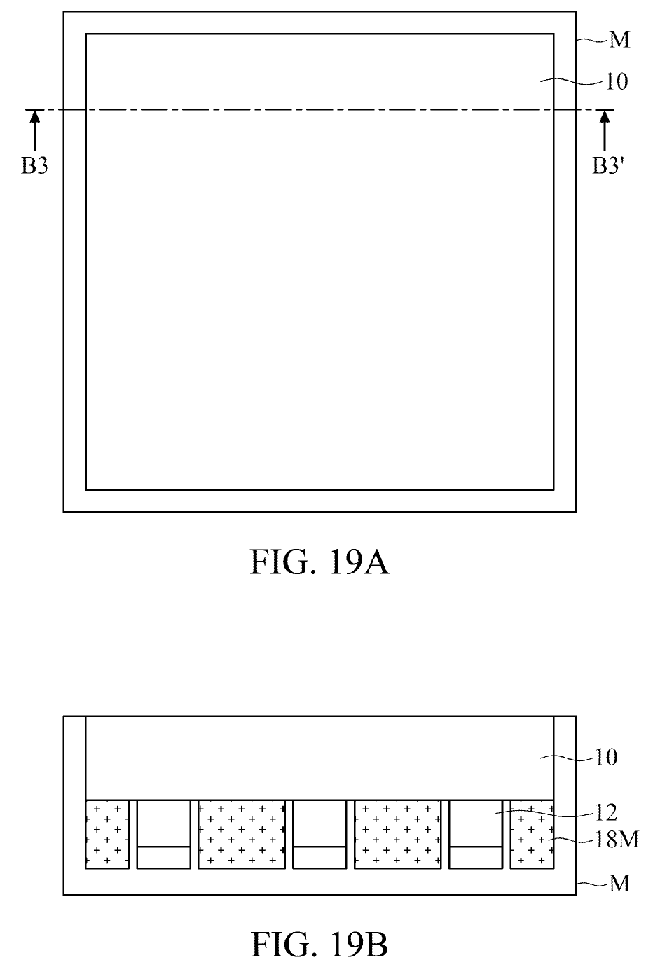

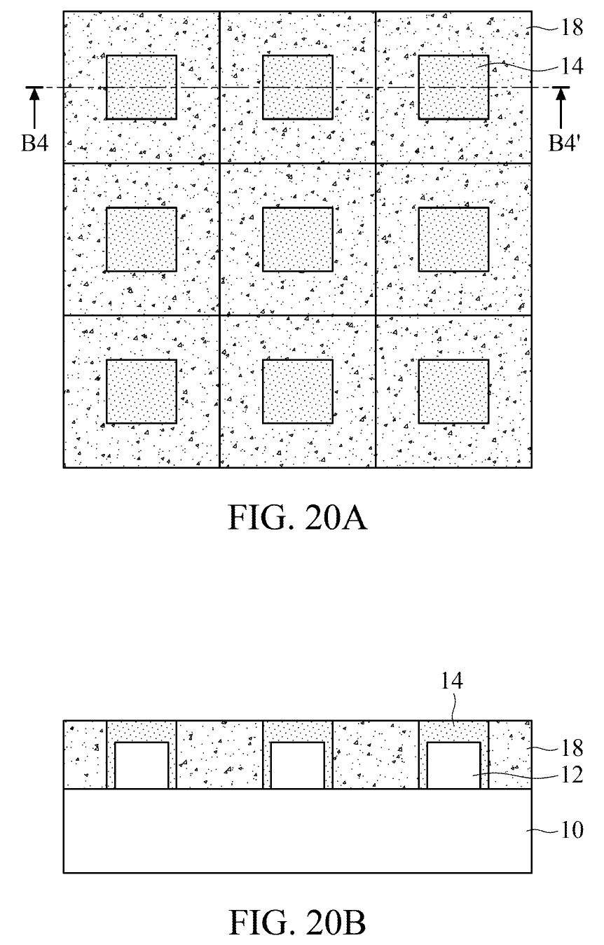

Referring to FIGS. 18A and 18B, on the other hand, a mold M for forming the dam 18 is prepared in advance, and the dam 18 is formed on the mold M. Referring to FIGS. 18A and 18B, FIG. 18A is a top view of a dam material 18M disposed on the mold M, in accordance with some embodiments of the present disclosure. FIG. 18B is a cross-sectional view taken along line B2-B2’ in FIG. 18A. The mold M includes a first recess R1 for forming the dam 18 and a second recess R2 for accommodating the light-emitting element 12 (as shown in FIGS. 19A and 19B) and part of the wavelength conversion layer 14 (as shown in FIGS. 20A and 20B), in which the first recess R1 surrounds the second recess R2. For example, the dam material 18M may be filled into the first recess R1 through a dispensing process or other suitable processes, in which the dam material 18M is a material used for forming the dam 18, but the present disclosure is not limited thereto.

Referring to FIGS. 18A and 18B, the dam material 18M may be a light-transmissive material, a semi-transmissive material, or a reflective material. For example, the light-transmissive material may be silicone, epoxy resin, a combination thereof, or other suitable light-transmissive materials, but the present disclosure is not limited thereto. For example, the semi-transmissive material may include a light-transmissive material and scattering particles, and the scattering particles are dispersed within the light-transmissive material, in which the concentration of the scattering particles within the light-transmissive material may be about 0.1% (w/w) to 75% (w/w), for example, about 0.2% (w/w), about 0.3% (w/w), about 0.5% (w/w), about 0.7% (w/w), about 1% (w/w), about 2% (w/w), about 3% (w/w), about 4% (w/w), about 5% (w/w), about 10% (w/w), about 20% (w/w), about 30% (w/w), about 40% (w/w), about 50% (w/w), about 60% (w/w), or about 70% (w/w), but is not limited thereto. The transmittance of the scattering particles for the peak emission wavelength of the light-emitting element 12 may be less than about 30%, for example, less than about 20%, less than about 10%, or less than about 5%, but is not limited thereto. For example, the scattering particles may be silicon dioxide or other suitable scattering particles. In some embodiments, the dam material 18M may be a reflective material. The reflective material may include a light-transmissive material and reflective fillers, and the reflective fillers are dispersed within the light-transmissive material. The light-transmissive material may be silicone, epoxy resin, a combination thereof, or other suitable materials, but the present disclosure is not limited thereto. The reflective filler may be titanium dioxide or other suitable reflective fillers, but is not limited thereto. When the dam material 18M for forming the dam 18 is the light-transmissive material, the transmittance of the dam 18 for the peak emission wavelength of the light-emitting element 12 may be greater than or equal to about 75%, for example, greater than or equal to about 80%, greater than or equal to about 90%, or greater than or equal to about 95%, but is not limited thereto. When the dam material 18M for forming the dam 18 is the semi-transmissive material, the transmittance of the dam 18 for the peak emission wavelength of the light-emitting element 12 may be about 35% to about 75%, for example, about 40%, about 50%, about 60%, or about 70%. When the dam material 18M is the reflective material, the transmittance of the dam 18 for the peak emission wavelength of the light-emitting element 12 may be less than about 35%, for example, less than or equal to about 30%, less than or equal to about 25%, less than or equal to about 20%, less than or equal to about 15%, less than or equal to about 10%, or less than or equal to about 5%, but is not limited thereto.

Referring to FIGS. 19A and 19B, subsequently, the lead frame 10 with the light-emitting element 12 mounted thereon is assembled with the mold M with the dam 18 formed therein. Referring to FIGS. 19A and 19B, FIG. 19A is a top view of the lead frame 10 with the light-emitting element 12 disposed on the mold M, in accordance with some embodiments of the present disclosure. FIG. 19B is a cross-sectional view taken along line B3-B3’ in FIG. 19A. For example, the light-emitting element 12 on the lead frame 10 is disposed in the second recess R2 of the mold M through a press-molding process or other suitable processes, and the lead frame 10 is in contact with the dam material 18M. Then, the dam material 18M may be cured to form the dam 18, thereby fixing the dam 18 on the lead frame 10 to facilitate subsequent removal from the mold M (as shown in FIGS. 20A and 20B), but the present disclosure is not limited thereto. For example, the dam material 18M may be cured into the dam 18 by photo-curing, thermal-curing, or other suitable curing methods. For example, the dam material 18M can be cured by light curing, heat curing, or other suitable curing methods, such that the dam material 18M is cured as the dam 18.

Referring to FIGS. 20A and 20B, then, after removing the mold M, the wavelength conversion layer 14 is filled to cover the light-emitting element 12. Referring to FIGS. 20A and 20B, FIG. 20A is a top view of the wavelength conversion layer 14 filled in the space surrounded by the dam 18, in accordance with some embodiments of the present disclosure. FIG. 20B is a cross-sectional view taken along line B4-B4’ in FIG. 20A. After removing the mold M, the wavelength conversion layer 14 is filled into the space surrounded by the dam 18, and the light-emitting element 12 is located in the space surrounded by the dam 18. For example, after removing the mold M, the wavelength conversion layer 14 is filled into the space surrounded by the dam 18 through a dispensing process or other suitable processes, such that wavelength conversion layer 14 covers the light-emitting element 12, but the present disclosure is not limited thereto.

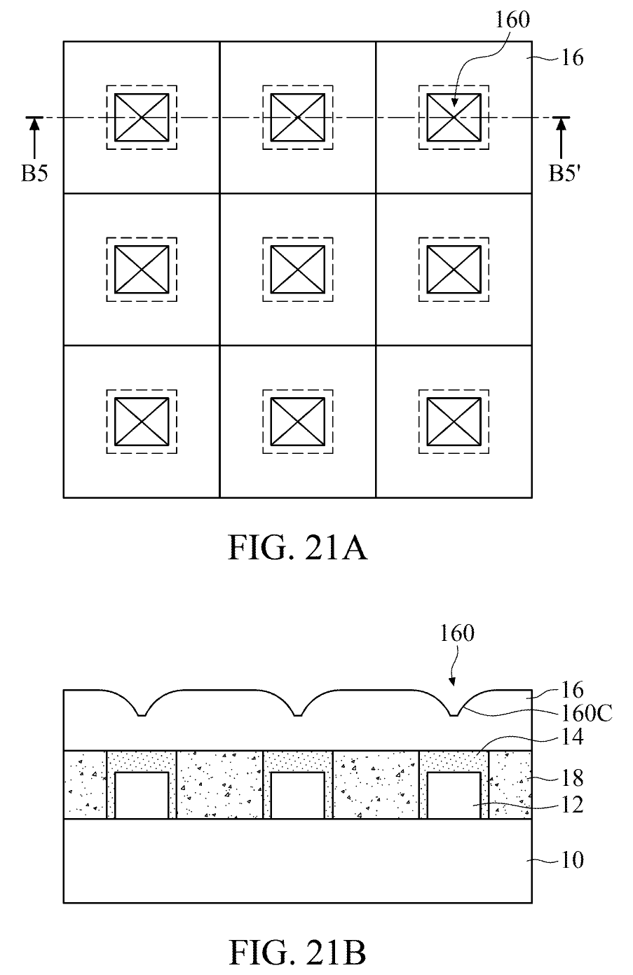

Referring to FIGS. 21A and 21B, subsequently, the light-adjusting structure 16 is disposed above the light-emitting element 12 and on the wavelength conversion layer 14. Referring to FIGS. 21A and 21B, FIG. 21A illustrates the light-adjusting structure 16 with the tapered curved profile 160C disposed above the light-emitting element 12 and on the wavelength conversion layer 14, and the dam 18, in accordance with some embodiments of the present disclosure. FIG. 21B is a cross-sectional view taken along line B5-B5’ in FIG. 21A. For example, the light-adjusting structure 16 is formed above the light-emitting element 12 and on the wavelength conversion layer 14 and the dam 18 through a press-molding process or other suitable processes, in which the light-adjusting structure 16 has the concave portion 160, and the concave portion 160 has the curved profile 160C tapering toward the light-emitting element 12. FIGS. 21A and 21B presents a plurality of connected light-emitting devices (such as the light-emitting device 1E shown in FIG. 8), the plurality of connected light-emitting devices may be separated into individual light-emitting devices through a dicing process or other suitable processes (such as the light-emitting device 1E shown in FIG. 8), but the present disclosure is not limited thereto.

It should be noted that, since the light-emitting devices 1, 1A, 1B, 2A, 2B, 3 illustrated in FIGS. 1-4 and 12-14 do not include the dam 18, the steps of forming the dam 18 shown in FIGS. 18A-18B, 19A-19B, and 20A-20B may be omitted. Instead, the wavelength conversion layer 14 with the required shape may be directly formed on the lead frame 10, and in the step illustrated in FIGS. 21A-21B, the light-adjusting structure 16 covering the light-emitting element 12 and the wavelength conversion layer 14 is formed by a press-molding process or other suitable processes. Furthermore, to form the light-adjusting structure 16 with the chamfered structure as illustrated in FIG. 13, a corresponding mold may, for example, be designed to shape the light-adjusting structure 16 during a press-molding process. However, the present disclosure is not limited thereto, and other suitable processes may also be employed to form the light-adjusting structure 16 with the desired shape.

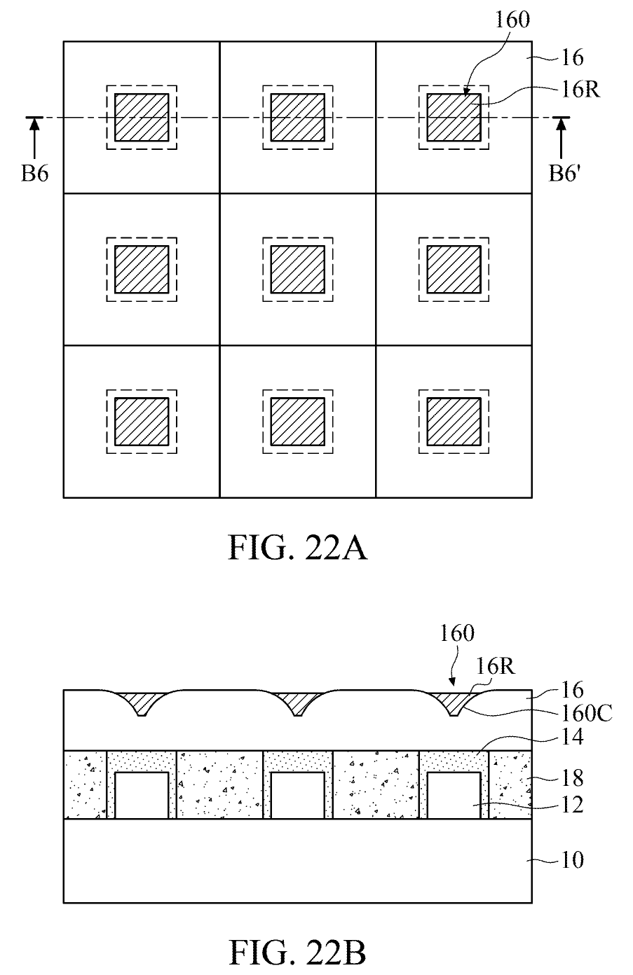

Referring to FIGS. 22A and 22B, in addition, to form the reflective layer 16R shown in FIGS. 10-13, after the process of FIGS. 21A and 21B, a process illustrated in FIGS. 22A and 22B may be further included as needed to fill the concave portion 160 of the light-adjusting structure 16 with the reflective layer 16R. Referring to FIGS. 22A and 22B, FIG. 22A is a top view of the reflective layer 16R filled in the concave portion 160 of the light-adjusting structure 16, in accordance with some embodiments of the present disclosure. FIG. 22B is a cross-sectional view taken along line B6-B6’ in FIG. 22A. For example, the reflective layer 16R may be disposed in the concave portion 160 of the light-adjusting structure 16 through a press-molding process or other suitable processes, such that the reflective layer 16R partially fills the concave portion 160.

In summary, the present disclosure uses a light-adjusting structure having light-transmissive properties and having the curved profile tapering toward the light-emitting element. The curved profile directs light toward the sides, thereby effectively increasing the light-emitting area while mitigating the shading effect present in the prior art, such that the light-emitting device achieves both a large light-emitting area and high luminous efficiency.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A light-emitting device, comprising:
a lead frame;
a light-emitting element, disposed on the lead frame;
a wavelength conversion layer, covering the light-emitting element; and
a light-adjusting structure, covering the light-emitting element and the wavelength conversion layer, and comprising a concave portion that has a curved profile tapering toward the light-emitting element.

2. The light-emitting device of claim 1, wherein the concave portion has an inverted flare shape.

3. The light-emitting device of claim 1, wherein the curved profile has a radius of curvature greater than 0.02 mm.

4. The light-emitting device of claim 1, wherein the concave portion includes a flat bottom surface.

5. The light-emitting device of claim 4, wherein the light-adjusting structure has a first width, the light-emitting element has a second width, the first width is greater than the second width.

6. The light-emitting device of claim 1, wherein the light-adjusting structure includes a light-transmissive material.

7. The light-emitting device of claim 6, wherein the light-adjusting structure further includes scattering particles dispersed within the light-transmissive material.

8. The light-emitting device of claim 7, wherein the scattering particles has a concentration of less than 50% (w/w).

9. The light-emitting device of claim 1, wherein the light-adjusting structure comprises a top portion with a chamfered structure.

10. The light-emitting device of claim 9, wherein the chamfered structure has a radius of curvature greater than 0.02 mm.

11. The light-emitting device of claim 1, further comprising:
a dam, disposed between the lead frame and the light-adjusting structure, and surrounding the light-emitting element and the wavelength conversion layer.

12. The light-emitting device of claim 11, wherein the dam comprises a plurality of discontinuous segments.

13. The light-emitting device of claim 1, further comprising:
a reflective layer disposed in the concave portion of the light-adjusting structure.

14. The light-emitting device of claim 13, wherein the reflective layer covers a part of the concave portion.

15. The light-emitting device of claim 13, wherein the reflective layer has a filling ratio from 0.1% to 30%.

16. The light-emitting device of claim 13, wherein the reflective layer has a first orthogonal projection area onto the lead frame, the light-emitting element has a second orthogonal projection area onto the lead frame, the first orthogonal projection area is larger than the second orthogonal projection area.

17. The light-emitting device of claim 13, wherein the reflective layer has a first orthogonal projection area onto the lead frame, the light-emitting element and the wavelength conversion layer have a sum of orthogonal projection areas onto the lead frame which is substantially equal to the first orthogonal projection area.

18. The light-emitting device of claim 13, wherein the reflective layer has a first orthogonal projection area onto the lead frame, the light-emitting element and the wavelength conversion layer have a sum of orthogonal projection areas onto the lead frame greater than the first orthogonal projection area.

19. The light-emitting device of claim 13, wherein the reflective layer comprises a light-transmissive material and a reflective filler dispersed within the light-transmissive material.

20. The light-emitting device of claim 19, wherein the reflective filler within the light-transmissive material has a concentration from 0.1% (w/w) to 30% (w/w).
